(19) United States
(12) Patent Application Publication
(10) Pub. No.: US 2024/0027002 A1
(43) Pub. Date: Jan. 25, 2024

(54) METHOD FOR COATING A SCREW ELEMENT, SCREW ELEMENT AND PIPE CONNECTION DEVICE

(71) Applicant: TI Automotive (Heidelberg) GmbH, Heidelberg (DE)

(72) Inventors: Andreas STAHN, Rauenberg (DE); Georg WEICK, Plankstadt (DE)

(21) Appl. No.: 18/023,349

(22) PCT Filed: Aug. 25, 2021
(86) PCT No.: PCT/IB2021/057799

§ 371 Date: Feb. 25, 2023

(30) Foreign Application Priority Data
Aug. 27, 2020 (EP) 20193157.3

(51) Int. Cl. F16L 19/028

(52) U.S. Cl. CPC F16L 19/0286

(57) ABSTRACT

A method for coating a screw element, in particular a screw element for connecting pipes, preferably motor vehicle pipes, wherein the screw element has at least one thread as well as at least one unthreaded contact surface. At least areas of the thread are provided with a first coating, and at least areas of the unthreaded contact surface are provided with a second coating. Both the first coating of the thread as well as the second coating of the unthreaded contact surface are applied to the thread or to the unthreaded contact surface via plasma coating.

### RELATED APPLICATIONS

This application is a 35 U.S.C. § 371 national phase of PCT International Application No. PCT/IB2021/057799, filed Aug. 25, 2021, which claims benefit of European Application No. 20193157.3, filed Aug. 27, 2020, the contents of which are incorporated herein by reference in their entirety.

### FIELD

The disclosure relates to a method for coating a screw element, in particular a screw element for connecting pipes, preferably for connecting motor vehicle pipes, wherein the screw element has at least one thread as well as at least one unthreaded contact surface, wherein at least areas of the thread are provided with a first coating, and wherein at least areas of the unthreaded contact surface are provided with a second coating. The disclosure further relates to a corresponding screw element as well as a pipe connection device for connecting pipes with a screw element.

### BACKGROUND

Methods of the kind described above as well as corresponding screw elements and pipe connection devices are known from practice in varying configurations. The screw elements are here often designed as screw fittings, with which a pipe, in particular a motor vehicle pipe, is connected to a connection element. For example, the pipes are used for brake fluids in motor vehicles.

It is already known to provide the screw elements or screw fittings with special coatings to influence the friction values. For example, it is known that the coating of the thread of the screw fitting has a higher friction value than a coating of the unthreaded contact surfaces of the screw fitting, for example on the underside of the screw head and/or at the end face of the screw fitting. A coating with a high friction value in the area of the thread is intended to hamper any inadvertent detachment of the screw connection. By contrast, the coating with a lower friction value in the area of the unthreaded contact surfaces diminishes the transfer of torsion forces to the parts or pipe ends to be connected. This makes it possible to avoid a torsion on the pipe in the screwing process, and a resultant reverse torque, which could lead to an undesired loosening of the screw connection.

In the coating measures known to date for such screw elements, the focus is placed in particular on wet chemical methods or galvanotechnical measures. We have discovered that the disadvantage to these methods is that the friction values of the applied coatings can vary relatively strongly from screw element to screw element. This necessitates time- and cost-intensive tests to determine whether the screw elements correspond to the requirements prescribed by the standards. In these known measures, the coating can often not be applied to the coated surface homogeneously enough. Different friction values can be observed over the coated surface. Of course, this is not desirable.

### SUMMARY

By contrast, the technical problem underlying the disclosure is to indicate a method of the kind mentioned at the outset, with which the disadvantages described above can be effectively avoided. The disclosure is further based upon the technical problem of indicating a corresponding screw element and a corresponding pipe connection device.

The instruction in the disclosure for resolving this technical problem involves a method for coating a screw element, in particular a screw element for connecting pipes, preferably of motor vehicle pipes, wherein the screw element has at least one thread as well as at least one unthreaded contact surface, wherein at least areas of the thread are provided with a first coating, and wherein at least areas of the unthreaded contact surface are provided with a second coating, wherein both the first coating of the thread as well as the second coating of the unthreaded contact surface or the unthreaded contact surfaces are applied to the thread or to the unthreaded contact surface(s) via plasma coating. According to a recommended embodiment of the disclosure, at least 80%, preferably at least 85%, of the threaded surface of the thread is provided with the first coating. It is recommended that at least 80%, preferably at least 85%, of the contact surface of an unthreaded contact surface of the screw element is provided with the second coating.

The disclosure is based upon the discovery that applying the first coating and the second coating via a plasma method makes it possible to reproducibly set the friction values of the coated areas of the screw element and keep the friction values of the respective surfaces nearly constant for screw elements coated one after the other. The disclosure is further based upon the discovery that the first and the second coating can be applied very homogeneously over the respective coated surface. The friction values are nearly constant over the coated surface.

It lies within the framework of the disclosure that the first coating has a friction value of μ1 and the second coating has a friction value of μ2, and that the first friction value μ1 is larger than the second friction value μ2. In an especially preferred embodiment of the disclosure, the first friction value μ1 measures at least two times, preferably at least three times, and especially preferably at least four times the second friction value μ2.

According to a proven embodiment of the disclosure, the layer thickness of the first coating measures 1 μm to 25 μm, and in particular 2 μm to 20 μm. It is recommended that the layer thickness of the second coating measures 5 μm to 100 μm, and in particular 5 μm to 50 μm.

According to an especially preferred embodiment of the disclosure, the first coating with the friction value μ1 is only applied to the thread, and the second coating with the friction value μ2 is only applied to the at least one unthreaded contact surface. In this embodiment, then, the first coating is only applied to the thread and not to the at least one unthreaded contact surface, and the second coating is only applied to the at least one unthreaded contact surface.

In another embodiment of the method according to the disclosure, the first coating with the friction value μ1 is applied to both the thread and also to the at least one unthreaded contact surface, and the second coating with the friction value μ2 is applied to the at least one unthreaded contact surface which covers the first coating there. In this embodiment, then, the entire screw element or at least the thread and the at least one unthreaded contact surface of the screw element are initially provided with the first coating, and then the second coating is applied to the first coating in the area of the unthreaded contact surface or in the area of the unthreaded contact surfaces, so that the second coating forms the outer surface on the unthreaded contact surface or on the unthreaded contact surfaces.

One especially preferred embodiment within the framework of the disclosure is characterized in that the used screw element is a screw bolt or a screw fitting, which has a thread designed like a male thread, at least areas of which are provided with the first coating. It lies within the framework of the disclosure that the end face of the screw fitting has an unthreaded contact surface, at least areas of which are provided with the second coating. It further lies within the framework of the disclosure that a thread-sided underside of a screw head of the screw fitting has an unthreaded contact surface, at least areas of which are provided with the second coating.

According to the disclosure, both the first coating as well as the second coating are applied via plasma coating. A specially recommended embodiment of the disclosure is characterized in that the plasma coating for the first coating and/or for the second coating is performed at normal pressure or at atmospheric pressure. Plasma coating could basically also take place at other pressures, for example in a vacuum. It lies within the framework of the disclosure that plasma coating is performed as a physical vapor deposition or as a chemical vapor deposition.

Advantageously a plasma coating device is used for plasma coating, and the material for the first coating and/or the material for the second coating is fed to the plasma coating device as a powder. It lies within the framework of the disclosure that the material for the first coating and/or the material for the second coating in the plasma coating device is converted into the gas phase, and is then deposited in a solid form onto the thread and/or onto the at least one unthreaded contact surface.

We have found that it has proven effective that the surface of the thread and/or of the at least one unthreaded contact surface that is to be coated are cleaned prior to coating, and are preferably cleaned with the help of the plasma coating device or cleaned by means of a plasma jet. This is then followed by coating with the first coating and/or with the second coating.

It is recommended that at least one material or at least one substance from the “metal, metal salt, polymer” group is used for the first coating and/or for the second coating. The first coating and/or second coating to be applied by means of plasma coating can basically consist or essentially consist of various organic and/or organometallic compounds and/or mixtures thereof. The first coating advantageously has a metal oxide as the metal salt, for example aluminum oxide and/or iron oxide. Within the framework of the disclosure, in particular polyolefins, polyimides, fluoropolymers and polyamides are possible as the polymers. According to an embodiment variant, the first coating has a polyamide and/or a polyimide as the polymer.

Advantageously the second coating has a lubricant that lowers the friction value of the coating. Preferably involved here is a fluoropolymer, in particular a polytetrafluoroethylene (PTFE) and/or molybdenum sulfide (MoS₂). According to one embodiment of the disclosure, the first coating and/or the second coating has at least one material or at least one substance from the “polyolefin, polyimide, polyamide, fluoropolymer, metal, metal salt” group.

The subject matter of the disclosure also relates to a screw element, in particular for connecting pipes and preferably for connecting motor vehicle pipes, wherein the screw element has at least one thread as well as at least one unthreaded contact surface, wherein at least areas of the thread are provided with a first coating, wherein at least areas of the at least one unthreaded contact surface are provided with a second coating, and wherein both the first coating of the thread as well as the second coating of the at least one unthreaded contact surface are applied via plasma coating. In an especially recommended embodiment of the disclosure, the screw element is a screw fitting with a male thread. At least areas of this thread are coated with the first coating.

The subject matter of the disclosure further relates to a pipe connection device for connecting pipes, in particular motor vehicle pipes, with a screw element, wherein a pipe is connected to the screw element, and wherein the screw element is connected to a connection element via a screwed connection. The screw element is coated according to the disclosure. Advantageously the screw element of the pipe connection device according to the disclosure is a screw fitting with an axial bore, with the axial bore being penetrated by a pipe, wherein the pipe end of the pipe has a flare, and wherein the unthreaded contact surface provided with the second coating abuts against the end face of the screw fitting on the rear side of the flare. The unthreaded contact surface at the end face of the screw fitting is provided with the second coating, and with this second coating abuts against the rear flare side of the flare of the pipe.

The disclosure is based upon the discovery that the method according to the disclosure can be used to reproducibly generate screw elements with two different coatings, each with a friction value set in a defined manner. It was found that screw elements coated one after the other by means of plasma coating according to the disclosure have hardly any deviations in the friction values of the two coatings. This makes it possible to eliminate time- and cost-intensive tests for determining whether the individual screw elements satisfy the requirements with respect to the friction values. The disclosure is further based upon the discovery that the varying layers generated by means of plasma coating according to the disclosure are each formed very homogeneously over their surface, and have no appreciable variations in friction values over the coated surface. The method according to the disclosure can do completely without wet-chemical or galvanotechnical procedural steps. The coating measures according to the disclosure can be implemented easily and with little effort, and in particular in a cost-effective manner.

### BRIEF DESCRIPTION OF THE DRAWINGS

The disclosure will be described in more detail below based upon a drawing that only illustrates an exemplary embodiment. Shown schematically on:

FIG. 1: is a longitudinal section through a screw element according to the disclosure designed as a screw fitting,

FIG. 2: is a pipe connection device with the screw fitting according to FIG. 1 and connected pipe, and

FIG. 3: is a schematic view of a plasma coating device for implementing the method according to the disclosure.

### DETAILED DESCRIPTION

The figures show a screw element according to the disclosure designed as a screw fitting 1, which preferably and in the exemplary embodiment is provided for connecting a pipe 2. In particular, the pipe 2 involves a motor vehicle pipe. The screw fitting 1 has a thread 3 as well as unthreaded contact surfaces 4 and 5. The unthreaded contact surface 4 is arranged at the end face of the screw fitting 1, and the unthreaded contact surface 5 is arranged on the thread-sided underside of the screw head 6 of the screw fitting 1.

In the exemplary embodiment, the thread 3 or the male thread of the screw fitting 1 is preferably completely provided with a first coating 7. In the exemplary embodiment, the two unthreaded contact surfaces 4, 5 are preferably completely provided with a second coating 8. The friction value μ1 of the first coating 7 is larger than the second friction value μ2 of the second coating 8. In the exemplary embodiment, the first friction value μ1 preferably measures five times the second friction value μ2. —In the exemplary embodiment, the screw fitting 1 preferably consists of metal or essentially of metal.

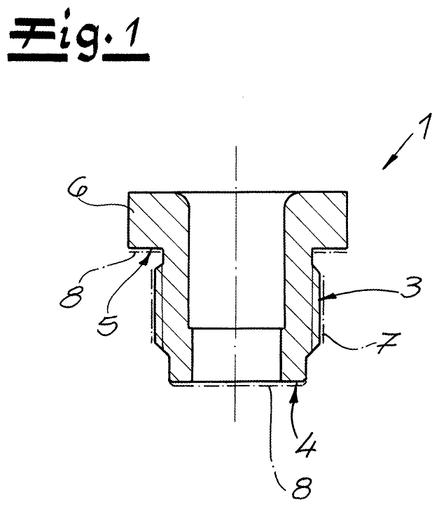

In the preferred embodiment of the screw fitting 1 shown on FIG. 1, the first coating 7 with the higher friction value μ1 was applied in the area of the thread 3 by means of plasma coating. The first coating 7 forms the outer surface of the screw fitting 1 in the area of the thread 3. The second coating 8 with the lower friction value μ2 was applied in the area of the unthreaded contact surfaces 4 and 5 by means of plasma coating. The second coating 8 forms the outer surface of the screw fitting 1 in the area of these unthreaded contact surfaces 4 and 5.

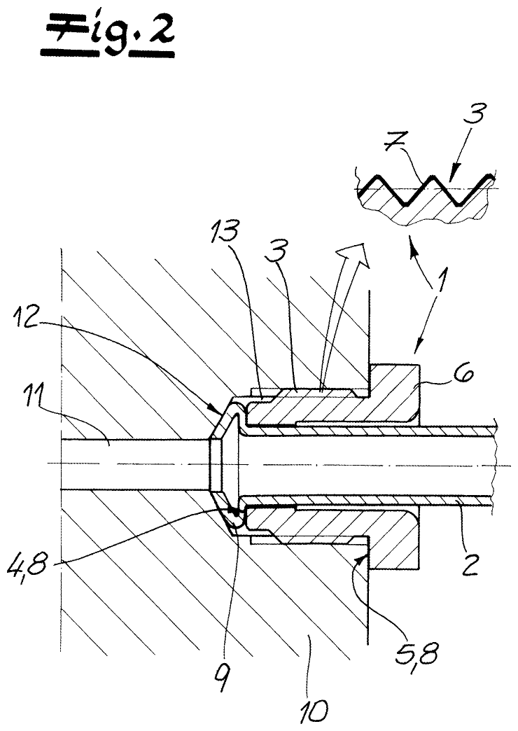

FIG. 2 shows a screw fitting 1 generated according to the disclosure in an operating state or a pipe connection device according to the disclosure with the screw fitting 1. In the exemplary embodiment, the pipe 2 preferably penetrates the screw fitting 1 in an axial direction, and the end of this pipe 2 has a face element, which in the exemplary embodiment is designed like a flare 9, as recommended. It lies within the framework of the disclosure that a metal flare 9 be involved, which in the exemplary embodiment is preferably integrally molded onto the pipe end. In the exemplary embodiment according to FIG. 2, the screw fitting 1 is screwed into a connection element designed as a connecting block 10. In the exemplary embodiment, the connecting block 10 best has an integrated second pipe 11. The end face sealing surface 12 of the screw fitting 1 presses the flare 9 against a connecting surface of the connecting block 10. For this purpose, the thread 3 or male thread of the screw fitting 1 is screwed into the blind hole 13 of the connecting block 10. In the exemplary embodiment, the blind hole 13 has a corresponding complementary female thread. The thread 3 or the male thread of the screw fitting 1 is provided with the first coating 7, which was applied according to the disclosure via plasma coating. The unthreaded contact surface 4 at the face end of the screw fitting has the second coating 8, which was likewise applied by means of plasma coating. The unthreaded contact surface 5 on the thread-sided underside of the screw head 6 is likewise provided with the second coating 8, which here as well was applied by means of plasma coating.

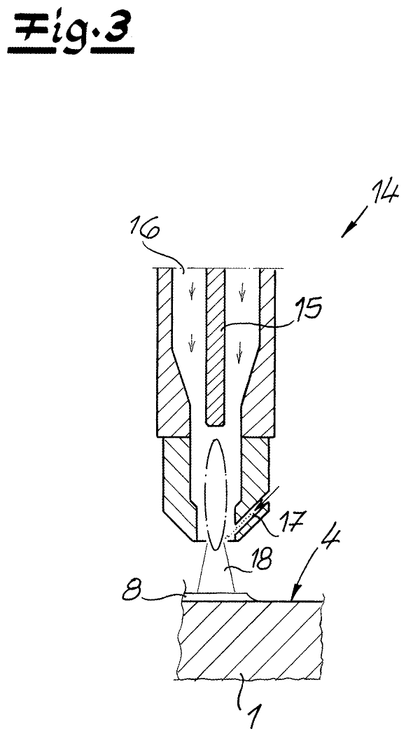

FIG. 3 shows a plasma coating device 14 suitable for the method according to the disclosure. In the exemplary embodiment according to FIG. 3, this plasma coating device 14 is used to apply the second coating 8 with the lower friction value μ2 to the unthreaded contact surface 4 at the end face of the screw fitting 1. In the usual manner, the plasma coating device has an electrode 15 as well as a gas supply line 16. In the exemplary embodiment, the material for the coating is preferably supplied through the channel 17 as a powder. The plasma jet 18 is discernible above the surface to be coated. —In a preferred embodiment, the surface to be coated can be cleaned prior to plasma coating with the plasma coating device or with its plasma jet 18, as was already pointed out above.

1. A method for coating a screw element for connecting pipes, wherein the screw element has at least one thread as well as at least one unthreaded contact surface, wherein at least areas of the thread are provided with a first coating, and wherein at least areas of the unthreaded contact surface are provided with a second coating, wherein both the first coating of the thread as well as the second coating of the unthreaded contact surface, are applied to the thread or to the unthreaded contact surface via plasma coating.

2. The method according to claim 1, wherein the first coating has a friction value μ1 and the second coating has a friction value μ2, and wherein the first friction value μ1 is larger than the second friction value μ2.

3. The method according to claim 1, wherein the first friction value μ1 measures at least two times the second friction value μ2.

4. The method according to claim 1, wherein the layer thickness of the first coating measures 1 μm to 25 μm, and/or wherein the layer thickness of the second coating measures 5 μm to 100 μm.

5. The method according to claim 1, wherein the used screw element is a screw bolt or a screw fitting, which has a thread designed like a male thread, at least areas of which are provided with the first coating.

6. The method according to claim 5, wherein the end face of the screw fitting has an unthreaded contact surface, at least areas of which are provided with the second coating, and/or wherein a thread-sided underside of a screw head of the screw fitting has an unthreaded contact surface, at least areas of which are provided with the second coating.

7. The method according to claim 1, wherein the plasma coating for the first coating and for the second coating is performed at normal pressure or at atmospheric pressure.

8. The method according to claim 1, wherein plasma coating is performed as a physical vapor deposition and/or as a chemical vapor deposition.

9. The method according to claim 1, wherein a plasma coating device is used for plasma coating, and wherein the material for the first coating and/or the material for the second coating is fed to the plasma coating device as a powder.

10. The method according to claim 1, wherein the material for the first coating and/or the material for the second coating in the plasma coating device is converted into the gas phase, and then deposited in a solid form onto the thread and/or onto the unthreaded contact surface.

11. The method according to claim 1, wherein at least one material from the “metal, metal salt, polymer” group is used for the first coating and/or the second coating.

12. A screw element manufactured based upon a method according to claim 1 for connecting pipes, wherein the screw element has at least one thread as well as at least one unthreaded contact surface, wherein at least areas of the thread are provided with a first coating, and wherein at least areas of the unthreaded contact surface are provided with a second coating, characterized in that both the first coating of the thread as well as the second coating of the unthreaded contact surface are applied via plasma coating.

13. A pipe connection device for connecting pipes, with a screw element according to claim 12, wherein a pipe is connected to the screw element, and wherein the screw element is connected to a connection element via a screwed connection.

14. The pipe connection device according to claim 13, wherein the screw element is a screw fitting with an axial bore, with the axial bore being penetrated by a pipe, wherein the pipe end of the pipe has a flare, and that the unthreaded contact surface provided with the second coating at the end face of the screw fitting abuts against the rear flare side of the flare.

15. Use of a screw element according to claim 12 in motor vehicle construction for fuel lines or hydraulic lines.

16. The method according to claim 1, wherein the first friction value measures at least three times the second friction value μ2.

17. The method according to claim 1, wherein the layer thickness of the first coating measures 2 μm to 20 μm, and/or wherein the layer thickness of the second coating measures 5 μm to 50 μm.
